(19) United States
(12) Patent Application Publication
(10) Pub. No.: US 2019/0065805 A1
(43) Pub. Date: Feb. 28, 2019

(54) DISPLAY DEVICE AND CONTROL METHOD THEREOF

(71) Applicant: BOE TECHNOLOGY GROUP CO., LTD., Beijing (CN)

(72) Inventor: Lijun ZHAO, Beijing (CN)

(21) Appl. No.: 15/737,823

(22) PCT Filed: Jun. 27, 2017
(86) PCT No.: PCT/CN17/90388

§ 371 Date: Nov. 8, 2018

(30) Foreign Application Priority Data
Dec. 27, 2016 (CN) 201611225885.0

(51) Int. Cl. G06K 9/00; G01S 15/89; G01S 7/52; G09G 3/3208; H01L 27/32

(52) U.S. Cl. CPC G06K 9/0002; G01S 15/8913; H01L 27/3225; G01S 7/52085; G09G 3/3208; G01S 15/8925

(57) ABSTRACT

A display device and a control method thereof are disclosed. The display device includes: a display panel and a plurality of ultrasonic assemblies disposed in a same layer. Each of the plurality of ultrasonic assemblies includes a piezoelectric layer and two electrodes which are respectively disposed on two surfaces of the piezoelectric layer.

### CROSS-REFERENCE TO RELATED APPLICATIONS

The present application is based upon International Application No. PCT/CN2017/090388, filed on Jun. 27, 2017, which is based upon and claims priority to Chinese Patent Application No. 201611225885.0, titled “display device and control method thereof” filed on Dec. 27, 2016, the entire contents of which are incorporated herein by reference.

### TECHNICAL FIELD

The present disclosure relates to the field of display technology, and more specifically, to a display device and a control method thereof.

### BACKGROUND

Currently, a wide range of electronic devices have fingerprint recognition function. More and more people are accustomed to performing various operations through the fingerprint recognition function, such as unlocking a screen, confirming payment or the like.

A display device having a fingerprint recognition function includes a display panel, a plurality of ultrasonic receiving assemblies disposed in the display panel, and a plurality of ultrasonic generating assemblies disposed outside the display panel. When performing fingerprint recognition, the ultrasonic generating assemblies emit ultrasonic, which is reflected by the finger and then received by the ultrasonic receiving components. The display device may recognize the fingerprint information consisting of valleys (concave portions in the finger) and ridges (convex portions in the finger) of the finger from the received ultrasonic according to different absorption rates of ultrasonic between the valleys and the ridges of the finger.

### SUMMARY

The embodiments of the present disclosure provide a display device and a control method of the display device.

According to a first aspect of the present disclosure, there is provided a display device including: a display panel; and a plurality of ultrasonic assemblies being arranged in a same layer, each of the plurality of ultrasonic assemblies includes a piezoelectric layer and two electrodes, and the two electrodes are respectively disposed on two surfaces of the piezoelectric layer.

In an embodiment, the plurality of ultrasonic assemblies are disposed on a light-exiting side of the display panel or on a side of the display panel that is opposite to the light-exiting side.

In an embodiment, the plurality of ultrasonic assemblies are disposed in the display panel.

In an embodiment, each of the ultrasonic assemblies further includes two electrode wirings, and the two electrode wirings are respectively coupled to the two electrodes.

In an embodiment, at least one of the two electrode wirings is formed integrally with a display structure in the display panel, and the display structure includes an electrode or a wiring in the display panel for implementing a display function.

In an embodiment, the display panel is an organic light-emitting diode (OLED) display panel, and the OLED display panel includes a light-emitting unit including an electroluminescent (EL) layer and a first electrode and a second electrode disposed at two sides of the EL layer; one of the two electrode wirings is formed integrally with the first electrode.

In an embodiment, the other one of the two electrode wirings is formed integrally with the second electrode.

In an embodiment, the display panel is further provided with a data line, and the other one of the two electrode wirings is formed integrally with the data line.

In an embodiment, at least one of the two electrode wirings is disposed in a same layer as a display structure in the display panel, and the display structure includes an electrode or a wiring in the display panel for implementing a display function.

In an embodiment, each of the ultrasonic assemblies is further coupled to an emitting control circuit including an emitting switch and an emitting power source. The emitting power source is coupled to the two electrodes through an emitting wire, is configured to apply a voltage of a preset frequency to the two electrodes through the emitting wire. The emitting switch is disposed on the emitting wire for controlling both ends of the emitting wire to be decoupled from or coupled with each other.

In an embodiment, each of the ultrasonic assemblies is further coupled to a receiving control circuit including a receiving switch and a receiving detector. The receiving detector is coupled to the two electrodes through a receiving wire and is configured to detect voltages of the two electrodes through the receiving wire. The receiving switch is disposed on the receiving wire for controlling both ends of the receiving wire to be decoupled from or coupled to each other.

In an embodiment, each of display regions in the display panel is provided with one of the ultrasonic assemblies, and each of the display regions includes at least one sub-pixel region.

In an embodiment, the two electrodes include a material of 3,4-ethylenedioxythiophene (PEDOT).

According to a second aspect of the present disclosure, there is provided a control method of a display device, which is applied to a display device including a display panel and a plurality of ultrasonic assemblies disposed in a same layer, and each of the plurality of ultrasonic assemblies includes a piezoelectric layer and two electrodes disposed on both surfaces of the piezoelectric layer respectively. The method includes: controlling each of the ultrasonic assemblies to alternately perform ultrasonic emitting and ultrasonic receiving when a fingerprint recognition instruction is received; acquiring ultrasonic received by each of the ultrasonic assemblies when performing ultrasonic receiving; and recognizing fingerprint information included in the ultrasonic.

In an embodiment, each of the ultrasonic assemblies includes two electrode wirings respectively coupled to the two electrodes, at least one of the two electrode wirings is a display structure in the display panel, and the display structure includes an electrode or a wiring in the display panel for implementing a display function. The controlling each of the ultrasonic assemblies to alternately perform ultrasonic emitting and ultrasonic receiving includes: controlling the display device to alternately perform display and fingerprint recognition, wherein when the display device performs display, the display panel displays images; and when the display device performs fingerprint recognition, each of the ultrasonic assemblies alternately performs the ultrasonic emitting and the ultrasonic receiving.

### BRIEF DESCRIPTION OF THE DRAWINGS

To describe the technical solutions in the embodiments of the present disclosure more clearly, the accompanying drawings required for describing the embodiments will be described briefly below. Apparently, the accompanying drawings in the following description show merely some embodiments of the present disclosure. For those skilled in the art, other drawings can be obtained based on these drawings without creative efforts.

FIG. 1 is a schematic structural diagram of a display device according to an embodiment of the present disclosure;

FIG. 2 is a schematic structural diagram of another display device according to an embodiment of the present disclosure;

FIG. 3 is a schematic structural diagram of another display device according to an embodiment of the present disclosure;

FIG. 4 is a schematic structural diagram of another display device according to an embodiment of the present disclosure;

FIG. 5 is a schematic structural diagram of another display device according to an embodiment of the present disclosure;

FIG. 6 is a schematic diagram of electrode wirings in a display device according to an embodiment of the present disclosure;

FIG. 7 is a schematic structural diagram of another display device according to an embodiment of the present disclosure;

FIG. 8 is a flowchart of a method for controlling a display device according to an embodiment of the present disclosure;

FIG. 9 is a timing diagram of the emission of ultrasonic in the embodiment shown in FIG. 8;

FIG. 10 is a flow chart of controlling each of ultrasonic assemblies in the embodiment shown in FIG. 8; and

FIG. 11 is a schematic diagram of fingerprint recognition in the embodiment shown in FIG. 8.

### DETAILED DESCRIPTION

To make the objectives, technical solutions, and advantages of the present disclosure more comprehensible, the embodiments of the present disclosure are further described in detail below with reference to the accompanying drawings.

In the process of fabricating a display device having a fingerprint recognition function, the inventor finds that the related art has at least the following problems: arranging ultrasonic receiving assemblies on the inner side of the display panel and arranging an ultrasonic generating assemblies on the outer side thereof would increase the overall thickness of the display device with a relatively thick display panel.

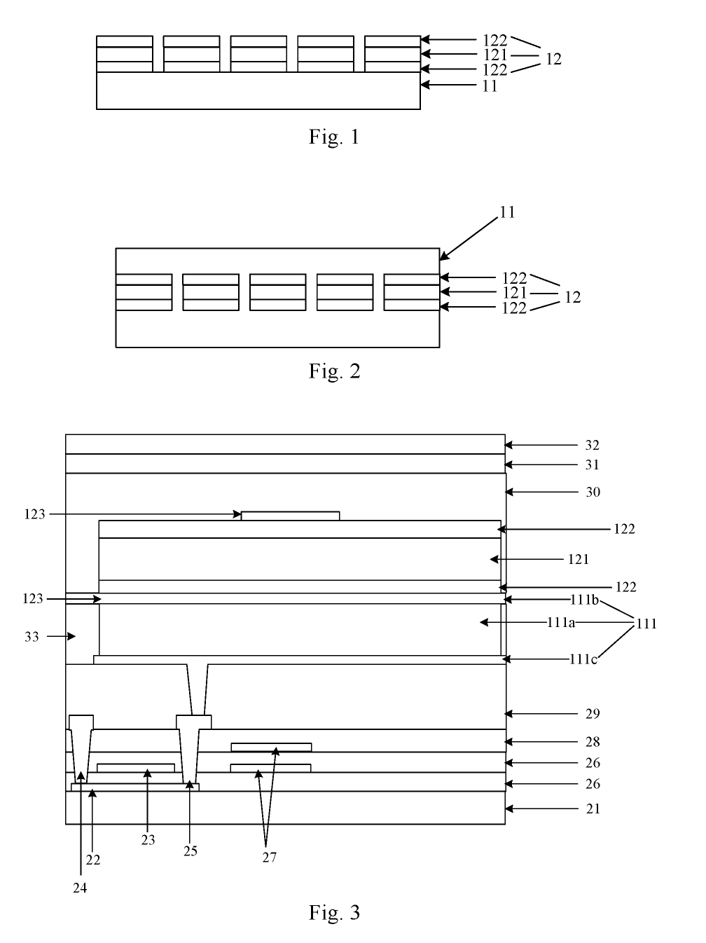

FIG. 1 is a schematic structural diagram of a display device according to an embodiment of the present disclosure. The display device may include a display panel 11 and a plurality of ultrasonic assemblies 12. The plurality of ultrasonic assemblies 12 are arranged in the same layer.

Each of the plurality of ultrasonic assemblies 12 includes a piezoelectric layer 121 and two electrodes 122. The two electrodes 122 are respectively disposed on two surfaces of the piezoelectric layer 121.

In this embodiment, each of the ultrasonic assemblies 12 may be used for emitting ultrasonic and receiving ultrasonic. Each of the ultrasonic assemblies 12 can apply a voltage of a predetermined frequency to the piezoelectric layer 121 through the two electrodes 122 to emit ultrasonic. The voltage generated by the piezoelectric layer 121 receiving ultrasonic may be detected by the two electrodes 122. That is, the display device provided by the embodiment of the present disclosure is a display device with a fingerprint recognition function, which emits ultrasonic and receives ultrasonic by using the ultrasonic assemblies.

In summary, in the display device provided in the embodiments of the present disclosure, the ultrasonic assemblies are disposed in the same layer, and are used for both emitting and receiving ultrasonic, therefore there is no need to arrange ultrasonic receiving assemblies and ultrasonic emitting assemblies separately. Therefore, the problem of thick display panel may be solved and a display panel with a decreased thickness may be realized.

FIG. 2 is a schematic structural diagram schematically illustrating another display device provided by an embodiment of the present disclosure. The display device includes some other preferable assemblies on the basis of the display device shown in FIG. 1, so that the display device provided in the embodiment of the present disclosure may have better performance.

A plurality of ultrasonic assemblies 12 are provided in the display panel 11.

In an embodiment, each of the ultrasonic assemblies 12 further includes two electrode wirings 123. The two electrode wirings 123 are respectively coupled to the two electrodes 122.

In an embodiment, at least one of the two electrode wirings 123 is integrally formed with a display structure of the display panel. The display structure includes an electrode or a wiring in the display panel for implementing the display function. For example, the display structure may include an electrode wiring such as a gate electrode, a source electrode or a drain electrode of a thin film transistor (TFT). The fact that the electrode wiring is integrally formed with the display structure refers to that an electrode or a wiring, which exists in the display panel for implementing display function, is used as the electrode wiring of the ultrasonic assembly.

In an embodiment, the display panel 11 is an organic light emitting diode (OLED) display panel. As shown in FIG. 3, the display panel includes a light emitting unit 111. The light emitting unit 111 includes an electroluminescent (EL) layer 111a and a first electrode 111b and a second electrode 111c disposed at both sides of the EL layer 111a. One of the two electrode wirings 123 is integrally formed with the first electrode 111b.

FIG. 3 illustrates a substrate 21 which may be made of polyimide (PI), an active layer 22, a gate electrode 23, a source electrode 24, a drain electrode 25, two gate insulating (GI) layers 26, a storage capacitor 27, an inter-layer dielectric (ILD) 28, a planarization layer 29, a thin film encapsulation (TFE) 30, a sealant 31, a top film 32, a pixel defining layer (PDL) 33. In FIG. 3, the second electrode 111c may be an anode, and the first electrode 111b may be a cathode. In FIG. 3, the other electrode wiring of the two electrode wirings 123 may be formed by a single patterning process separately.

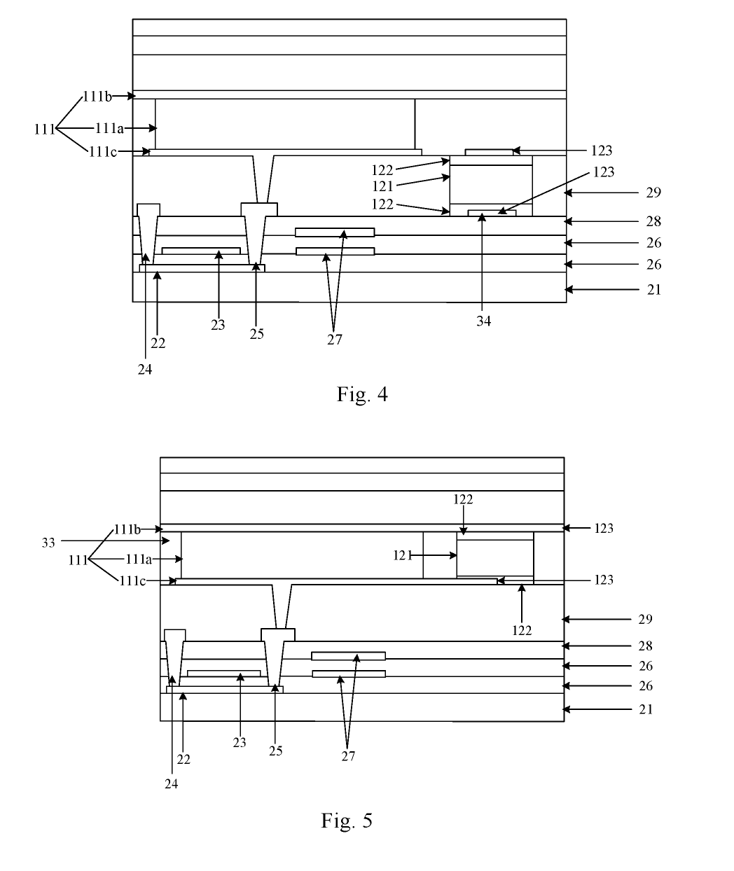

In an embodiment, as shown in FIG. 4, which is a schematic structural diagram of another display device according to an embodiment of the present disclosure, a data line 34 is further disposed in the display panel. The data line 34 is used to provide gray scale signal when the display paned is displaying images. The data line 34 may be disposed in the same layer as the source electrode 24 and the drain electrode 25. One of the two electrode wirings 123 is integrally formed with the second electrode 111c, and the other one of the two electrode wirings 123 is integrally formed with the data line 34. Meanings of other reference numerals in FIG. 4 may be referred to that in FIG. 3, which are not repeated herein.

In an embodiment, as shown in FIG. 5, which is a schematic structural diagram of another display device according to an embodiment of the present disclosure, in the display device, one of the two electrode wirings 123 is integrally formed with the first electrode 111b, and the other one of the two electrode wirings 123 is integrally formed with the second electrode 111c. Meanings of other reference numerals in FIG. 5 may be referred to that in FIG. 3, which are not repeated herein.

FIG. 3 to FIG. 5 are schematic diagrams illustrating three kinds of structures in which the electrode wiring of the ultrasonic assembly is shared with the display structure in the display panel. The electrode wiring of the ultrasonic assembly may also be shared with other display structure in the display panel, which is not limited by the embodiments of the present disclosure. In addition, when the display panel is another type of display panel, the electrode wiring of the ultrasonic assembly may still be integrally formed with the display structure in the display panel. When the electrode wiring and the display structure in the display panel are integrally formed, the electrode wiring and the display structure can be formed through a single patterning process, thereby omitting a patterning process for forming the electrode wiring and reducing the material for forming the electrode wiring without increasing the number of layers in the display panel. Thus the thickness of the display panel is reduced.

In an embodiment, in each of the display devices provided in the embodiments of the present disclosure, the material of the two electrodes of the ultrasonic assembly includes 3,4-ethylenedioxythiophene (PEDOT). PEDOT is a transparent and elastic material which may serve as the electrode of the ultrasonic assembly.

In an embodiment, in each of the display devices provided in the embodiments of the present disclosure, the material of the piezoelectric layer of the ultrasonic assembly includes, but is not limited to, piezoelectric ceramic transducer (PZT).

In an embodiment, at least one of the two electrode wirings of the ultrasonic assembly is disposed in the same layer as the display structure in the display panel. When the electrode wiring and the display structure in the display panel are disposed in the same layer, the electrode wiring and the display structure can be formed through a single patterning process, thereby omitting a patterning process for forming the electrode wiring without increasing the number of the layers in the display panel, thereby reducing the thickness of the display panel.

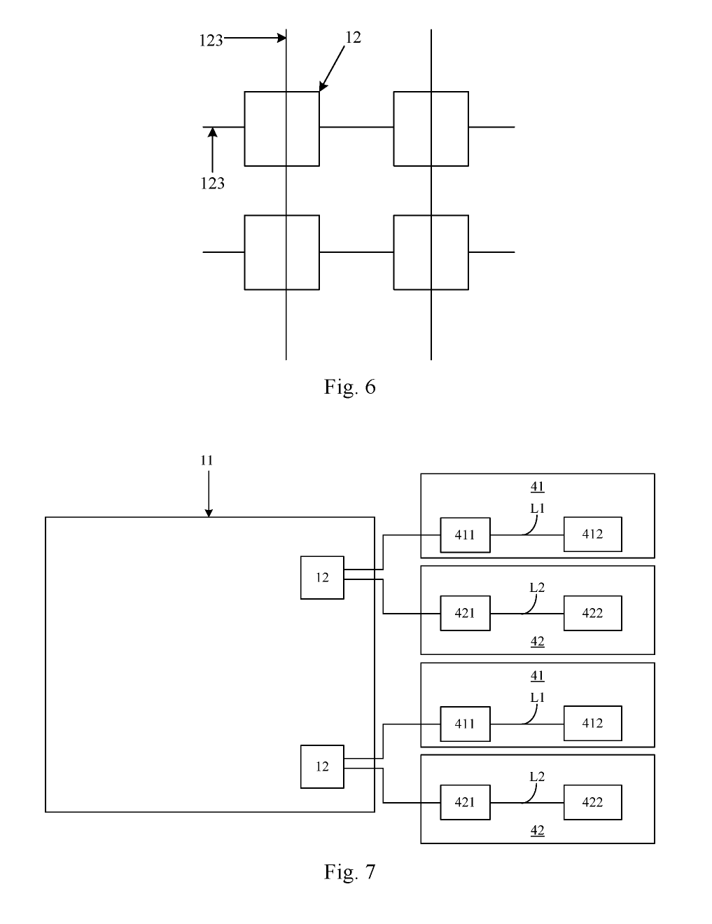

FIG. 6 schematically illustrates a plan view of ultrasonic assemblies 12 and two electrode wirings 123 in a display device according to an embodiment of the present disclosure. It can be seen that the electrode wirings at one side of the ultrasonic assemblies in each column may be coupled together, and the electrode wirings at the other side of the ultrasonic assemblies in each row may be coupled together.

As shown in FIG. 7, in the display device, each of the ultrasonic assemblies 12 is further coupled with an emitting control circuit 41. The emitting control circuit includes an emitting switch 411 and an emitting power source 412. An emitting wire L1 is coupled between the emitting power source 412 and both electrodes of any ultrasonic assembly 12. The emitting power source 412 is used to apply voltage of a preset frequency to both electrodes through the emitting wire L1. The emitting switch 411 is disposed on the emitting wire L1 for controlling both ends of the emitting wire L1 to be decoupled from or coupled with each other.

In an embodiment, each of the ultrasonic assemblies 12 is further coupled with a receiving control circuit 42. The receiving control circuit 42 includes a receiving switch 421 and a receiving detector 422. A receiving wire L2 is coupled between the receiving detector 422 and the two electrodes of the ultrasonic assembly 12. The receiving detector 422 is used to detect voltages of the two electrodes through the receiving wire L2. The receiving switch 421 is disposed on the receiving wire L2 for controlling both ends of the receiving wire L2 to be decoupled from or coupled with each other.

The emitting control circuit 41 and the receiving control circuit 42 may be located outside the display panel 11. Optionally, the emitting switch 411 in the emitting control circuit 41 and the receiving switch 421 in the receiving control circuit 42 are located inside the display panel 11, while the emitting power source 412 in the emitting control circuit 41 and the receiving detector 422 in the receiving control circuit 42 are located outside the display panel 11.

In an embodiment, each of display areas in the display panel 11 is provided with one ultrasonic assembly 12, and each of the display areas includes at least one sub-pixel area. That is, one ultrasonic assembly may be provided in each sub-pixel area on the display panel 11. Optically, one ultrasonic assembly may be provided in each pixel area on the display panel 11. Optically, one ultrasonic assembly may be provided in each multiple-pixels area on the display panel 11.

In an embodiment, as shown in FIG. 1, a plurality of ultrasonic assemblies 12 may also be disposed on the light exiting side of the display panel 11 or the side thereof that is opposite to the light exiting side. In this way, the fingerprint recognition function may be provided to the display panel that does not have fingerprint recognition function.

In summary, in the display device provided by the embodiments of the present disclosure, the ultrasonic assemblies are disposed in the same layer, and are used for both emitting and receiving ultrasonic, therefore there is no need to arrange ultrasonic receiving assemblies and ultrasonic emitting assemblies separately. Therefore, the problem of thick display panel in the related art may be solved and an effect of reducing the thickness of a display panel may be obtained.

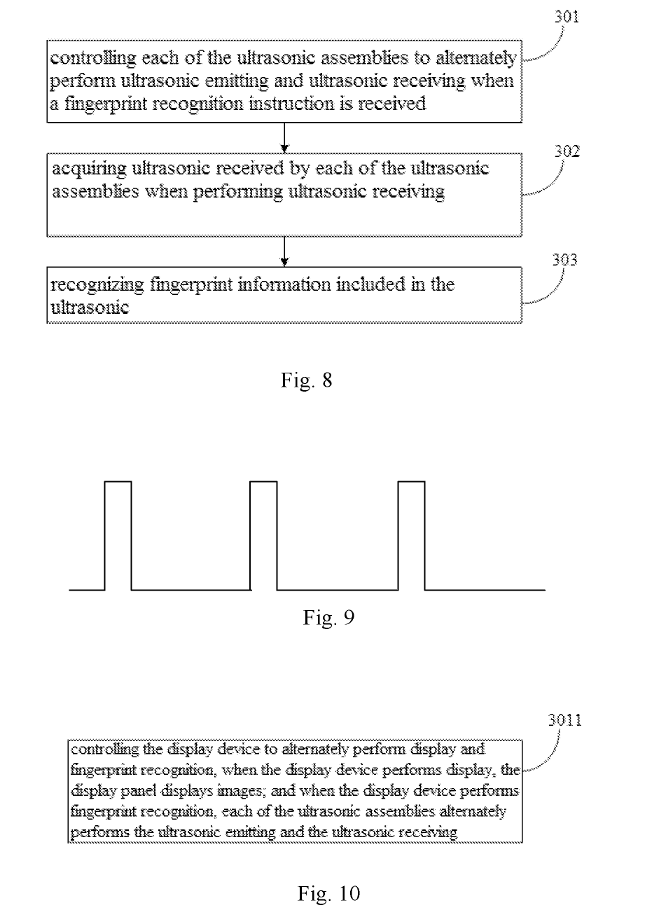

FIG. 8 is a flowchart of a method for controlling a display device according to an embodiment of the present disclosure. The method for controlling the display device is applied to any one of the display devices shown in FIG. 2 to FIG. 5. The display device may include a display panel and a plurality of ultrasonic assemblies arranged in a display panel. Each of the plurality of ultrasonic assemblies includes a piezoelectric layer and two electrodes respectively disposed on both surfaces of the piezoelectric layer. The method for controlling the display device includes the following steps.

In step 101, each of the ultrasonic assemblies is controlled to alternately emit and receive ultrasonic when a fingerprint recognition instruction is received.

The display device may control each of the ultrasonic assemblies to alternately perform ultrasonic emitting and receiving when it receives the fingerprint identification instruction. For example, as shown in FIG. 9, which shows a timing diagram of the emission of ultrasonic by the ultrasonic assembly in the display device, the protruding region represents the ultrasonic assembly is emitting ultrasonic, and the non-protruding region represents the ultrasonic assembly is receiving ultrasonic. It can be seen that the ultrasonic assemblies emit ultrasonic for a period shorter than the period for which the ultrasonic assemblies receive ultrasonic.

In addition, each of the ultrasonic assemblies in the display device may include two electrode wirings. The two electrode wirings are respectively coupled to the two electrodes. At least one of the two electrode wirings is the display structure in the display panel. The display structure includes an electrode or a wiring in the display panel for implementing the display function. In this case, as shown in FIG. 10, this step may include: a sub-step 1011, controlling the display device to perform display and fingerprint recognition alternately. When the display device performs display, the display panel displays images. When the display device performs fingerprint recognition, each of the ultrasonic assemblies emits and receives ultrasonic alternately.

When the display structure in the display panel and the electrode wiring in the ultrasonic assemblies are formed integrally, in order to avoid interference with the normal display of the display panel during the fingerprint detection, the display and the fingerprint recognition may be alternately performed in different time periods. In an embodiment, the time period for the display device to perform display may be much longer than the time period for the display device to perform fingerprint recognition. In this way, the impact of fingerprint recognition on the normal display of the display device may be further reduced.

In addition, the display device may control portions of the plurality of ultrasonic assemblies to emit ultrasonic, and at the same time, control the other portions of the plurality of ultrasonic assemblies to receive ultrasonic. The ultrasonic assemblies emitting ultrasonic and the ultrasonic assemblies receiving ultrasonic may alternately arranged.

In step 102, the ultrasonic, received by each of the ultrasonic assemblies when performing ultrasonic receiving, is acquired.

In step 103, the fingerprint information included in the ultrasonic is recognized.

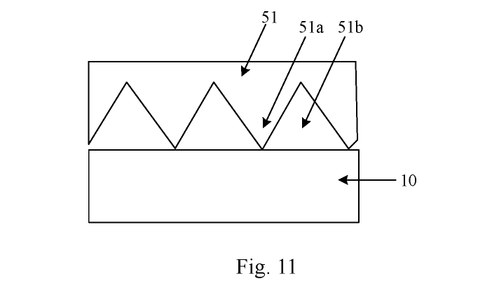

As shown in FIG. 11, there is a gap between the valley 51b of the finger 51 and the display device 10, and the ridge 51a is in direct contact with the display device 10. The air in the gap between the valley 51b and the display device 10 has a different absorptivity from that of the finger 51 to the ultrasonic emitted from the display device. Thus, the ultrasonic energy from the ridge 51a and that from the valley 51b are different. The display device may acquire the fingerprint information by analyzing the distribution of the ultrasonic energy.

To sum up, in the control method for the display device provided in the embodiments of the present disclosure, the emitting of the ultrasonic and the receiving of the ultrasonic are alternately performed by the ultrasonic assembly without separately providing ultrasonic receiving assembly and ultrasonic generating assembly, so that the problem of thick display panel in the related art may be solved and the thickness of the display panel may be reduced.

Persons skilled in the art should understand that all or part of the steps in the foregoing embodiments may be implemented by hardware or by instructing relevant hardware through program. The program may be stored in a computer-readable storage medium. The storage medium mentioned above may be a read only memory, a magnetic disk or an optical disk.

The above is only the preferred embodiments of the present disclosure and is not intended to limit the present disclosure. Any modifications, equivalent substitutions, improvements, etc. within the spirit and principle of the present disclosure should be included in the protection scope of the present disclosure.

1. A display device, comprising:
a display panel; and
a plurality of ultrasonic assemblies disposed in a same layer,
wherein each of the plurality of ultrasonic assemblies comprises a piezoelectric layer and two electrodes, and the two electrodes are respectively disposed on two surfaces of the piezoelectric layer.

2. The display device according to claim 1, wherein the plurality of ultrasonic assemblies are disposed on one of a light-exiting side of the display panel and a side of the display panel that is opposite to the light-exiting side.

3. The display device according to claim 1, wherein the plurality of ultrasonic assemblies are disposed in the display panel.

4. The display device according to claim 3, wherein each of the ultrasonic assemblies further comprises two electrode wirings, and the two electrode wirings are respectively coupled to the two electrodes.

5. The display device according to claim 4, wherein at least one of the two electrode wirings is formed integrally with a display structure in the display panel, and the display structure comprises an electrode or a wiring in the display panel for implementing a display function.

6. The display device according to claim 5, wherein the display panel is an organic light-emitting diode (OLED) display panel, and the OLED display panel comprises a light-emitting unit comprising an electroluminescent (EL) layer and a first electrode and a second electrode respectively disposed at two sides of the EL layer;
one of the two electrode wirings is formed integrally with the first electrode.

7. The display device according to claim 6, wherein the other one of the two electrode wirings is formed integrally with the second electrode.

8. The display device according to claim 6, wherein the display panel is further provided with a data line, and the other one of the two electrode wirings is formed integrally with the data line.

9. The display device according to claim 3, wherein at least one of the two electrode wirings is disposed in a same layer as a display structure in the display panel, and the display structure comprises an electrode or a wiring in the display panel for implementing a display function.

10. The display device according to claim 1, wherein each of the ultrasonic assemblies is further coupled to an emitting control circuit comprising an emitting switch and an emitting power source,
the emitting power source is coupled to the two electrodes through an emitting wire, and is configured to apply a voltage of a preset frequency to the two electrodes through the emitting wire,
the emitting switch is disposed on the emitting wire for controlling both ends of the emitting wire to be decoupled from or coupled with each other.

11. The display device according claim 1, wherein each of the ultrasonic assemblies is further coupled to a receiving control circuit comprising a receiving switch and a receiving detector,
the receiving detector is coupled to the two electrodes through a receiving wire and is configured to detect voltages of the two electrodes through the receiving wire,
the receiving switch is disposed on the receiving wire for controlling both ends of the receiving wire to be decoupled from or coupled to each other.

12. The display device according to claim 1, wherein each of display regions in the display panel is provided with one of the ultrasonic assemblies, and each of the display regions comprises at least one sub-pixel region.

13. The display device according to claim 1, wherein the two electrodes comprise a material of PEDOT.

14. A control method of a display device, wherein the display device comprises a display panel and a plurality of ultrasonic assemblies disposed in a same layer, and each of the plurality of ultrasonic assemblies comprises a piezoelectric layer and two electrodes disposed on both surfaces of the piezoelectric layer respectively, the method comprising:
controlling each of the ultrasonic assemblies to alternately perform ultrasonic emitting and ultrasonic receiving when a fingerprint recognition instruction is received;
acquiring ultrasonic received by each of the ultrasonic assemblies when performing ultrasonic receiving; and
recognizing fingerprint information included in the ultrasonic.

15. The method according to claim 14, wherein each of the ultrasonic assemblies comprises two electrode wirings respectively coupled to the two electrodes, at least one of the two electrode wirings is a display structure in the display panel, and the display structure comprises an electrode or a wiring in the display panel for implementing a display function,
the step of controlling each of the ultrasonic assemblies to alternately perform ultrasonic emitting and ultrasonic receiving comprises:
controlling the display device to alternately perform display and fingerprint recognition, wherein when the display device performs display, the display panel displays images; and when the display device performs fingerprint recognition, each of the ultrasonic assemblies alternately performs the ultrasonic emitting and the ultrasonic receiving.
